(19) United States
(12) Patent Application Publication
(10) Pub. No.: US 2025/0044386 A1
(43) Pub. Date: Feb. 6, 2025

(54) BALANCED FORCE SHIM COIL ARRAY

(71) Applicant: The Johns Hopkins University, Baltimore, MD (US)

(72) Inventors: Ehud J. SCHMIDT, Baltimore, MD (US); Aravindan KOLANDAIVELU, Baltimore, MD (US); Mirko HROVAT, Baltimore, MD (US); Henry R. HALPERIN, Baltimore, MD (US)

(73) Assignee: The Johns Hopkins University, Baltimore, MD (US)

(21) Appl. No.: 18/708,455

(22) PCT Filed: Nov. 2, 2022
(86) PCT No.: PCT/US2022/048731

§ 371 Date: May 8, 2024

Related U.S. Application Data
(60) Provisional application No. 63/276,967, filed on Nov. 8, 2021.

(51) Int. Cl. G01R 33/3875; G01R 33/565

(52) U.S. Cl. CPC G01R 33/3875; G01R 33/56563

(57) ABSTRACT

A device for magnetic resonance artifact correction includes an array of shim coils sequentially arranged to receive a current, such that a first force arising from an interaction of a magnetic field with the current in one shim coil is balanced by a second force on the array arising from interactions of the magnetic field with the current in other shim coils when the array is operated within an imaging volume of a magnetic resonance system. The device includes a frame of non-ferromagnetic material, to provide selectable positioning of the array, and a signal processor to use a measurement of a magnetic field inhomogeneity within a region of the imaging volume, to determine a current for the shim coils and coordinates for positioning the array within the imaging volume, such that applying the current to the array at the coordinates generates a correction field to reduce the magnetic field inhomogeneity.

### CROSS-REFERENCE OF RELATED APPLICATION

This application claims priority to U.S. Provisional Application No. 63/276,967, filed Nov. 8, 2021, which is incorporated herein by reference in its entirety.

### GOVERNMENT SUPPORT

This invention was made with government support under grants R01 HL094610, R01 HL157259, and R01 EB022011 awarded by the National Institutes of Health. The government has certain rights in the invention.

### BACKGROUND

### 1. Technical Field

Some embodiments relate to magnetic resonance imaging, and more particularly to magnetic field inhomogeneity correction.

### 2. Discussion of Related Art

Implantable Cardioverter Defibrillators (ICDs) are implanted in patients to prevent sudden cardiac death by electrically pacing the heart or delivering an electric shock when the device detects a potentially lethal arrhythmia. These arrhythmias commonly occur in the setting of a prior myocardial infarction. In the United States, ICDs are implanted in 150,000 patients per year, and there are over 2 million patients with implanted devices.

ICDs may be constructed as a flat “disk-like” shaped box that is placed over the rib cage beneath the skin and subcutaneous fat layers, with lead wires that go from this box to selected cardiac chambers. The box may contain the battery of the system and a ferromagnetic transformer that is used in order to inductively charge the ICD's capacitor. The ferromagnetic transformer, found even in MRI-conditional ICD units which have been rendered MRI-safe from incurring heating effects resulting from the MRI scanner's radio-frequency pulses, as well as rendered safe from reprogramming resulting from the MRI scanner's gradient pulses, creates a magnetic field around it. However, even MRI-conditional ICD units are sometimes counter-indicated for cardiac MRI scans due to large artifacts resulting from the ferromagnetic transformer.

Since the ICD box is generally situated in the upper chest (and frequently on the left side), the ferromagnetic transformer may be distanced 6 to 15 cm from portions of the heart. The distance of regions of the heart from the ferromagnetic transformer depends on the placement location of the box in the chest, the patient's anatomy (the thickness of the fat layers below the ICD, etc.), and the location and orientation of the heart.

Cardiac MRI (CMR) is an emerging area of MRI with a growing number of procedures each year. CMR deals with the diagnosis and treatment of cardiovascular disease using several MR imaging techniques, to investigate vascular anatomy and the chambers of the heart. In the areas where the heart is closest to the transformer, the superposition of the transformer's field, which strongly varies spatially, on the MRI scanner's homogeneous static (BO) magnetic field leads to a strongly inhomogeneous field. The size of the field inhomogeneity may be expressed in several different ways, such as magnetic field units as milli-Tesla (mT), as Parts Per Million of the main field (PPM), or as a Frequency offset (in Hertz) since 1 PPM is 63.8 Hertz or 123.2 Hertz at 1.5 T and 3 T, respectively. Field inhomogeneities of the order of 0.15 mT or 100 PM or more have been observed in patients with implanted ICDs.

Magnetic inhomogeneity leads to spatial distortions of the image, referred to as image artifacts. These image artifacts may include “pile up effects,” which are areas of the image where the geometry is shrunken so that the image elements (voxels) have higher intensity, causing the region to appear larger or smaller than it should be. The artifacts may also include areas where no signal is seen, e.g., a “black hole” in the image, due to the field inhomogeneity in the region exceeding the acquisition frequency boundaries of the specific sequence. The effects of the field inhomogeneity in the heart may be exacerbated by the physiological motion of the heart since the magnetic field inhomogeneity is variable during MR image acquisition. One reason for the variable inhomogeneity is that the heart moves relative to the position of the ferromagnetic transformer, and image acquisition may span several cardiac and respiratory cycles. Accordingly, the magnetic field inhomogeneities may affect different image components with varying degrees, which reduces image coherency, and therefore leads to reduced image quality (e.g., spatial and temporal resolution, inter-tissue contrast).

The different MR sequence types (including but not limited to Spin Echo (SE), Gradient Recalled Echo (GRE), Echo Planar Imaging (EPI), and Spiral Imaging), as well as the specific imaging parameters used with them, are sensitive to different levels of static magnetic field homogeneity. This sensitivity determines the location volume, and the topology of the region in the heart where the MR Imaging picture is considerably distorted geometrically or completely unseen (i.e., a “black hole” is seen in the image). Specialized MRI sequences have been developed to help with this issue, termed “wide-band GRE sequences” which are GRE sequences that are still able to acquire data in the presence of 4 KHz (e.g., ˜0.10 mT, or ˜62 PPM at 1.5T or ˜31 PPM at 3 T) magnetic field inhomogeneity. Wide-band sequences considerably reduce the region of the heart that cannot be imaged, but in many patients (and especially for those that do not have thick fat layers between the ICD and rib cage) the resulting images still contain residual black holes, considerable spatially distorted regions, and reduced image fidelity (e.g., spatial blurring, reduced inter-tissue contrast) due to severe motion artifacts in the presence of the field inhomogeneity.

Commonly-used sequences in CMR for assessing cardiac function include steady-state free precession (SSFP) sequences, which can only tolerate ˜1.0 KHz of field inhomogeneity, and consequently cannot be used in most of the ICD patients. Another important application of CMR is in the assessment of patients with diseases that result in ischemic (or fibrotic) regions such as in patients after heart attacks, where the objective is to detect the scarred regions of the anatomy. Typically, imaging of these scarred regions is performed with late gadolinium enhancement (LGE) sequences, which are inversion-recovery gradient echo (IR-GRE) sequences that are acquired a long time (e.g., ˜15 minutes) after contrast injection. Some wide-band sequences are modifications of standard IR-GRE sequences which allow LGE scans of patients implanted with ICDs, who are at risk of future diseases or require intervention. Since standard LGE scans are already lower in SNR relative to other MR sequences, the wide-band LGE sequences in the presence of a strong static field inhomogeneity are frequently blurred and very low in inter-tissue contrast.

### SUMMARY

An embodiment of the present invention is a device for magnetic resonance artifact correction, including an array of multiple shim coils that are sequentially arranged to receive a current, such that a first force on the array arising from an interaction of a magnetic field with the current in any one of the shim coils is balanced by a second force on the array arising from interactions of the magnetic field with the current in all other shim coils when the array is operated within an imaging volume of a magnetic resonance system. The device further includes a frame composed of non-ferromagnetic material positioned proximate to the imaging volume, the frame being configurable to provide selectable positioning of the array within the imaging volume. The device further includes a signal processor configured to receive a measurement of a magnetic field inhomogeneity within a selected region of the imaging volume, and, using the measurement of the magnetic field inhomogeneity, determine a current for the shim coils and a set of coordinates for positioning the array within the imaging volume, such that applying the current to the array at the set of coordinates generates a correction field to reduce the magnetic field inhomogeneity within the selected region of the imaging volume.

Another embodiment of the present invention is a magnetic resonance system including a magnet system configured to provide a substantially homogenous magnetic field over an imaging volume in the absence of ferromagnetic materials proximate to the imaging volume, and a magnetic field gradient system positioned proximate to the imaging volume, the magnetic field gradient system being configured to generate spatial encoding in the substantially homogeneous magnetic field. The magnetic resonance system further includes a radiofrequency (RF) system arranged proximate to the imaging volume and configured to acquire multiple MR signals from the imaging volume, and a device for magnetic resonance artifact correction. The device includes an array of multiple shim coils that are sequentially arranged to receive a current, such that a first force on the array arising from an interaction of a magnetic field with the current in any one of the shim coils is balanced by a second force on the array arising from interactions of the magnetic field with the current in all other shim coils when the array is operated within the imaging volume. The device further includes a frame composed of non-ferromagnetic material positioned proximate to the imaging volume, the frame being configurable to provide selectable positioning of the array within the imaging volume. The device further includes a signal processor configured to receive a measurement of a magnetic field inhomogeneity within a selected region of the imaging volume, and, using the measurement of the magnetic field inhomogeneity, determine a current for the shim coils and a set of coordinates for positioning the array within the imaging volume, such that applying the current to the array at the set of coordinates generates a correction field to reduce the magnetic field inhomogeneity within the selected region of the imaging volume.

### BRIEF DESCRIPTION OF THE DRAWINGS

Further objectives and advantages will become apparent from a consideration of the description, drawings, and examples.

FIG. 1 conceptually illustrates a magnetic resonance (MR) system of some embodiments, having a shimming system that reduces a magnetic field inhomogeneity arising from the presence of a medical device.

FIG. 2 illustrates mitigation of a magnetic field inhomogeneity created by an ICD using a superimposed magnetic field generated by a shim coil assembly of some embodiments.

FIG. 3 illustrates examples of field inhomogeneity in a patient with an implanted ICD, and how corrections for the inhomogeneity are implemented in some embodiments.

FIG. 4 shows an example of a balanced-force MRI shim coil assembly used in some embodiments.

FIG. 5 shows multiple views of a frame assembly of some embodiments.

FIG. 6 illustrates a volunteer subject on a patient table of an MRI system, positioned inside a frame assembly.

FIG. 7 conceptually illustrates a shimming system for performing shim coil validation tests in some embodiments.

FIG. 8 illustrates a schematic of a filter circuit used in some embodiments for a shim coil assembly.

FIG. 9 illustrates the results of experimental testing using the shimming system of FIG. 7.

FIG. 10 illustrates magnetic field maps for the experiments in FIG. 9.

FIG. 11 illustrates a flowchart for a process in which the shape of the dipole model is optimized.

FIG. 12 illustrates a flowchart for a process in which the shim coil location is optimized.

FIG. 13 illustrates a flowchart for a process in which the target ROI's location and shape are both optimized.

FIG. 14 illustrates another embodiment of a shim coil assembly mounted to a plastic frame assembly.

FIG. 15 illustrates frames of video taken during real-time shimming for several different scenarios.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed, and other methods developed, without departing from the broad concepts of the current invention.

All references cited anywhere in this specification, including the Background and Detailed Description sections, are incorporated by reference as if each had been individually incorporated.

As used herein, the term “shimming” refers to a process of correction of a magnetic field inhomogeneity (e.g., during magnetic resonance imaging (MRI) or nuclear magnetic resonance (NMR) experiments). Since the inhomogeneities may cause image artifacts which degrade signal quality, and therefore shimming is also a process to correct these artifacts and improve signal quality. An inhomogeneity may arise from any of a number of sources, including but not limited to the presence of bone, foreign metal, and voids of air. For example, an inhomogeneity may be created or caused by the placement near the imaging volume of objects or medical devices (e.g., an ICD) that contain ferromagnetic components.

As used herein, the term “shim coil” refers to a coil that during operation, corrects the magnetic field inhomogeneity. As an example, MRI shim coils are coils that are intended to remove or reduce inhomogeneities in an MR system's static magnetic field (BO). In order to effectively perform shimming, a shim coil may be calibrated to determine the amount of current flowing through the coil and to determine the position of the shim coil within the magnetic field. The terms “shim coil array,” “shim coil assembly,” and “shim coil” may be used interchangeably in the below discussion.

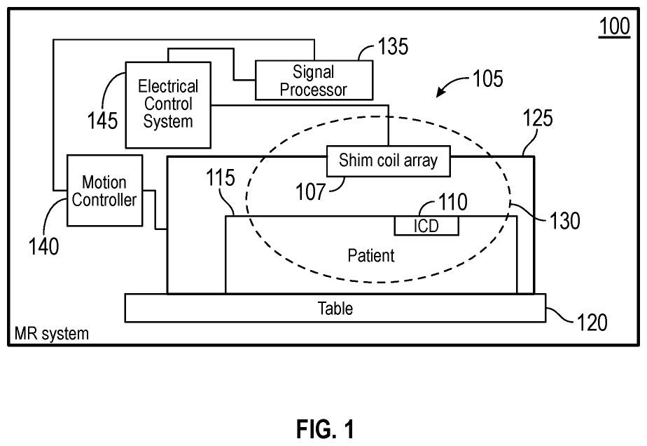

FIG. 1 conceptually illustrates a magnetic resonance (MR) system 100 of some embodiments, having a shimming system 105 that reduces a magnetic field inhomogeneity arising from the presence of a medical device. In the example of FIG. 1, the medical device is an ICD 110 that is implanted in a patient 115, and the MR system 100 is an MRI scanner having a patient table 120 that supports the patient 115 during an MRI scan. As an example, the shimming system 105 is safe for use in commercial MRI scanners and may be placed inside the bore of an MRI scanner during a scan of the patient 115, in a location which is above the chest of a patient.

In some embodiments, the shimming system 105 includes a force-balanced static magnetic field shim coil assembly 107 comprised of an array of multiple shim coils. The shim coil assembly 107 may be equivalently referred to as a shim coil or a shimming device. In some embodiments, the shim coil assembly 107 may be placed anywhere within the MR system 100. For example, the shim coil assembly 107 may be placed outside any MRI radio-frequency receive-array coils (not shown in FIG. 1) of the MR system 100. Such receive-array coils may include, but are not limited to, body array coils placed on the surface of the patient 115, or spine array coils placed beneath the patient 115, or beneath the patient table 120.

Since the shim coil assembly 107 may be used inside the MRI bore, and its current is ramped up and down within the strong magnetic field of the MR system 100 (which can induce very strong forces on the shim coil assembly 107), the shim coil assembly 107 may be configured to have a balanced torque and/or a balanced force, so that changing the current will not cause the shim coil assembly 107 to move, rotate, or deform within the bore.

In some embodiments, the multiple shim coils within the shim coil assembly 107 are sequentially arranged to receive a current, such that when the shim coil assembly 107 is operated within an imaging volume 130 (denoted by a dashed oval in FIG. 1) of the MR system 100, a first force on the shim coil assembly 107 (arising from an interaction of a magnetic field with the current in any one of the shim coils) is balanced by a second force on the shim coil assembly 107 (arising from interactions of the magnetic field with the current propagating within all the other shim coils).

In some embodiments, the force-balanced shim coil assembly 107 has a large shim volume and can be moved inside the bore without resistance, and used during imaging without the coil moving. The specific coil design of some embodiments is based on a limited number of relatively long linear coil segments, which can be optimized to provide a maximal correction field while minimizing the current amplitude required to correct the perturbation of the magnetic field by the ICD 110. For example, in some embodiments, the shim coil assembly 107 uses two coils placed in opposing directions that are driven in series, so that the shim coil assembly 107 is balanced in force and torque. In other embodiments, more than two coils may be used, and positioned to achieve balance in force and torque during operation.

The shim coil assembly 107 may be placed inside the MRI bore, quite close to the patient 115, with its powering cabling running to the MRI room's penetration panel (not shown in FIG. 1). The reduced current from a large number of turns allows for use of thinner cables. The balanced force reduces the risk of motion of the shim coil assembly 107 when current is driven into it, so the shim coil assembly 107 structure does not need to be as strongly anchored to the patient table 120.

In some embodiments, the shimming system 105 further includes a frame assembly 125 positioned proximate to the imaging volume 130 of the MR system 100. The frame assembly 125 may be securely anchored to the patient table 120 (e.g., an MRI stretcher). In some embodiments, the frame assembly 125 allows the shim coil assembly 107 to be moved, so that the frame assembly 125 is able to accommodate a variety of patients of differing sizes and in whom the ICD 110 may be implanted in different locations.

In some embodiments, the frame assembly 125 is composed of non-ferromagnetic material that is not magnetic or electrically conductive. For example, the frame assembly 125 may be constructed of an MR-compatible material, such as a non-ferrous and/or non-conducting material or alloy, including but not limited to a plastic or fiberglass.

The frame assembly 125 may be configurable to provide selectable positioning of the shim coil assembly 107 at least partially within the imaging volume 130. For example, the frame assembly 125 may allow the shim coil assembly 107 to be securely moved in three spatial directions (x, y, z) within the magnet bore, so that the shim coil assembly 107 can be used for patients with ICDs placed at various locations in the chest. The actual motion of the shim coil assembly 107 can be controlled in some embodiments by a motion controller system (not shown in FIG. 1) that is coupled physically to the frame assembly 125. For example, the motion controller system may use motors (e.g., pneumatic motors) to physically move the frame assembly 125 up/down or in/out, and move the shim coil assembly 107 left/right. Other types of motors are contemplated, including hydraulic motors and piezoelectric motors.

In some embodiments, the shim coil assembly 107 can be used correct the magnetic field inhomogeneity arising from the presence of the ICD 110 by using measures of the field inhomogeneity, which are obtained from MRI multiple-echo acquisitions. For example, the shimming system 105 may include a signal processor 135 configured to use data from MRI acquisitions to map the magnetic field inhomogeneity within a selected region of the imaging volume 130. The signal processor 135 may be configured to use the measurement of the magnetic field inhomogeneity to determine (a) a current for the shim coil assembly 107 and (b) a set of coordinates for positioning the shim coil assembly 107 at least partially within the imaging volume 130, such that applying the determined current to the shim coil assembly 107 while positioned at the determined set of coordinates generates a correction field to reduce the magnetic field inhomogeneity within the selected region of the imaging volume 130.

For example, in some embodiments, the signal processor 135 executes software to provide an initial estimate of the location and strength of a dipole magnetic field that can correct the magnetic field inhomogeneity. The initial estimate triggers a movement of the shim coil assembly 107 to an initial location in the bore where the shim coil assembly 107 can be used to correct the specific inhomogeneity. In some embodiments, these initial steps are repeated to perform an iterative correction of the initial estimates, so that optimal imaging of the anatomy can be performed. The signal processor 135 may be in some embodiments part of a computer system (not shown in FIG. 1) to execute software used to calculate the field map and determine the optimal location and current for the shim coil assembly 107.

As discussed above, in some embodiments, a software program is used to compute a magnetic field map, e.g., a perturbed static magnetic field map, of the perturbed static magnetic field in the presence of an ICD 110. The magnetic field map may be computed in some embodiments based on a phase map acquired using a magnetic resonance imaging pulse sequence, including but not limited to a dual-echo Ultrashort Echo-Time (UTE) or a dual-echo Gradient-echo (GRE) sequence. As discussed above, the software program may use the computed magnetic field map to provide a desired location for the shim coil assembly 107 to be placed, and further use the magnetic field map to determine the desired current that should be driven through the shim coil assembly 107 in order to perform the correction of the magnetic field inhomogeneities.

As discussed above, a mapping sequence, such as but not limited to a UTE sequence, may be used in some embodiments to acquire data over the volume of interest. This data is used by the software program to compute the perturbed static magnetic field map. As an example, a UTE sequence may have a bandwidth (e.g. 784 KHz at 1.5 T) that is much larger than the bandwidth of conventional MRI sequences (e.g., up to 6 KHz at 1.5 T), and can therefore detect much larger field inhomogeneities.

In some embodiments, after computing the perturbed static magnetic field map in the presence of the ICD, in some embodiments the software program may fit a dipole-shaped magnetic field profile to the required correction field, and then use the fitted dipole-field shape to compute (a) the optimal three-dimensional location of the center of the shim coil assembly 107, as well as (b) the magnitude and direction of the current required to correct the perturbed field.

In some embodiments, the software provides output to a user (not shown in FIG. 1) who manually moves the shim coil assembly 107 by adjusting the frame assembly 125. In some embodiments, the frame assembly 125 includes a motion controller 140, and the software directly communicates with the motion controller 140 to move the shim coil assembly 107 without manual intervention.

In some embodiments, the software provides output to a user (not shown in FIG. 1) who manually configures an electrical control system 145 (e.g., a power supply) to provide the specified current to the shim coil assembly 107. In some embodiments, the shimming system 105 includes an electrical control system 145, and the software directly communicates with the electrical control system 145 to control the current through the shim coil assembly 107.

In some embodiments, the shim coil assembly 107 may be able to correct inhomogeneities of the order of 0.15 mT in the selected region of the imaging volume 130 (the selected region also referred to as a volume of interest), without significantly increasing the field distortion outside the volume of interest. The use of multiple windings (or turns) within the shim coil assembly 107 may prevent introducing currents greater than 10 amperes into the MR system 100. In some embodiments, using a DC current along with a large series inductor may prevent the shim coil assembly 107 from coupling with gradient coils (not shown in FIG. 1) of the MR system 100, and thereby avoid or reduce image artifact creation.

In some embodiments, the shim coil assembly 107 may reduce inhomogeneities to the order of 0.05 mT (1600 Hz at 1.5T) within a 5×5×5 cm³ region in the heart, which will enable the use of many MRI sequences in this region.

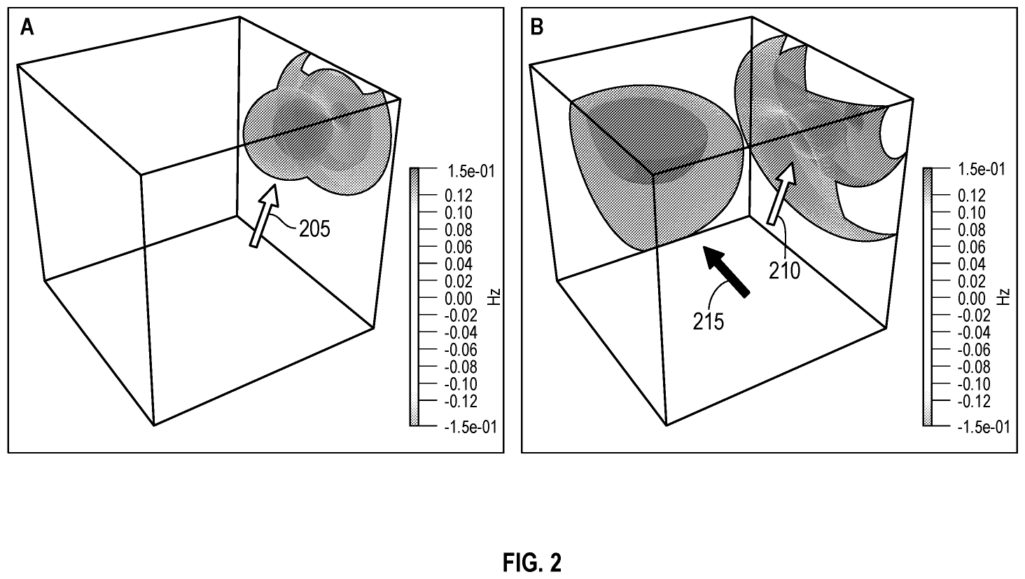

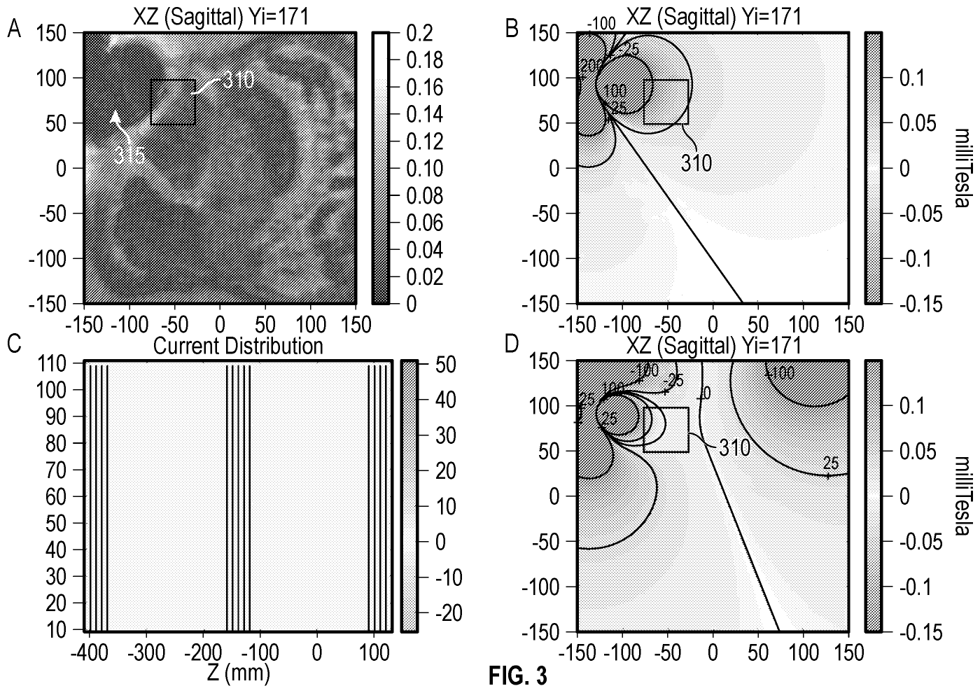

FIG. 2 illustrates mitigation of a magnetic field inhomogeneity created by an ICD using a superimposed magnetic field generated by a shim coil assembly 107 of some embodiments. Panel A shows a magnetic field (denoted by arrow 205) imposed by an ICD transformer (not shown in FIG. 2) approximated by a dipole magnetic field. This dipole field frequently renders areas of the heart at a very large field shift from the main field, so that these areas cannot be imaged with most sequences. Panel B illustrates how a shim coil assembly 107 applies a superimposed magnetic field to reduce the field shift in the desired region (indicated by arrow 210) to improving imaging of that region. This may come at the expense of increasing field shift in other regions (indicated by arrow 215).

The applications of the above-described shimming system 105 are not limited solely to ICDs, but in other embodiments, can also be applied to correcting for magnetic field inhomogeneities due to other (e.g., non-MRI compatible) implanted devices, including but not limited to pacemakers, vascular stents, chamber closure devices, as well as orthopedic implants, located in different parts of the body. The shimming system 105 may also be used in some embodiments for correcting for physiological magnetic-field inhomogeneities, including but not limited to air soft-tissue interfaces in the lower head or spine, and lung-heart interfaces. The shimming system 105 can also be applied in some embodiments to imaging different regions of the body at high magnetic fields (e.g., 3 Tesla, 7 Tesla or even higher), which have exacerbated inhomogeneity effects whose severity scales with the magnetic field.

In some embodiments, the shimming system 105 can be applied to moving ferromagnetic particles in the body to specified locations by producing magnetic field gradients (albeit with larger currents than would be used for merely correcting inhomogeneity effects). In some embodiments, the shimming system 105 can provide the ability to perform scans with pulse sequences (e.g., EPI, SSFP, etc.) that require higher magnetic field homogeneity in higher field MRI scanners, or within reduced homogeneity MRI scanners.

FIG. 3 illustrates examples of field inhomogeneity in a patient with an implanted ICD, and how corrections for the inhomogeneity are implemented in some embodiments.

Panel A of FIG. 3 illustrates an example of artifacts observed in MRI images of patients with an ICD, acquired with an ultra-short echo time (UTE) sequence that has a very wide bandwidth. The image shows a sagittal MRI image of the patient's cardiac region, displaying ICD-induced field distortions (magnetic field inhomogeneities). The box 310 delineates a region of interest (ROI) within which the resulting image artifacts need to be corrected. Since the ROI is part of the heart, is highly distorted and there is an extensive black void (denoted by arrow 315) in the image to the left of the square.

Panel B of FIG. 3 shows a sagittal static magnetic field (BO) map of the field distortion (in milliTesla, or mT) created fitting a dipole model to the magnetic field-map generated by high-bandwidth dual-echo ultra-short echo time (UTE) MRI scans. The box 310 denoting the ROI is again shown for reference. The fitted field validates that the artifact does indeed behave similarly to magnetic dipoles. Areas of very high field inhomogeneity are shown in darker shades, which are the cause of the image distortion in Panel A. Each contour shown is 25 parts-per-million (PPM).

Panel C of FIG. 3 shows a top view of the current pattern in a single-winding shim coil array of some embodiments used to correct for the dipole field distortion observed in Panel B. The dimensions are in millimeters (mm), with Z along the horizontal direction, and the current in the coil is 51 amps. This configuration fits the shim coil array inside the MRI bore, by combining straight shim segments with varying currents propagating on the segments. A field correction is implemented via linear coil segments of varying intensity and polarity, as shown. The legend to the right of the figure explains the correspondence of the gray-scale to current. Some segments carry positive currents and other segments carry negative currents. This arrangement minimizes the required currents for canceling the ICD field over the Region of Interest (ROI) in the heart denoted by box 310.

Panel D of FIG. 3 shows the calculated corrected field profile in mT after applying the shim current, with contours at 25 ppm intervals. After applying the field correction, in the box 310 there is a far smaller region of high-intensity, and larger regions of lighter shades (regions with less than 25 PPM BO distortion).

The following discussion describes technical details of various embodiments of a force-balanced static magnetic-field shim coil array. In some cases, like reference numerals have been used to refer to the same or similar components. A detailed description of such components may be omitted, and the following discussion may focus on the differences between these embodiments. Any of the various features discussed with any one of the embodiments discussed herein may also apply to and be used with any other embodiments.

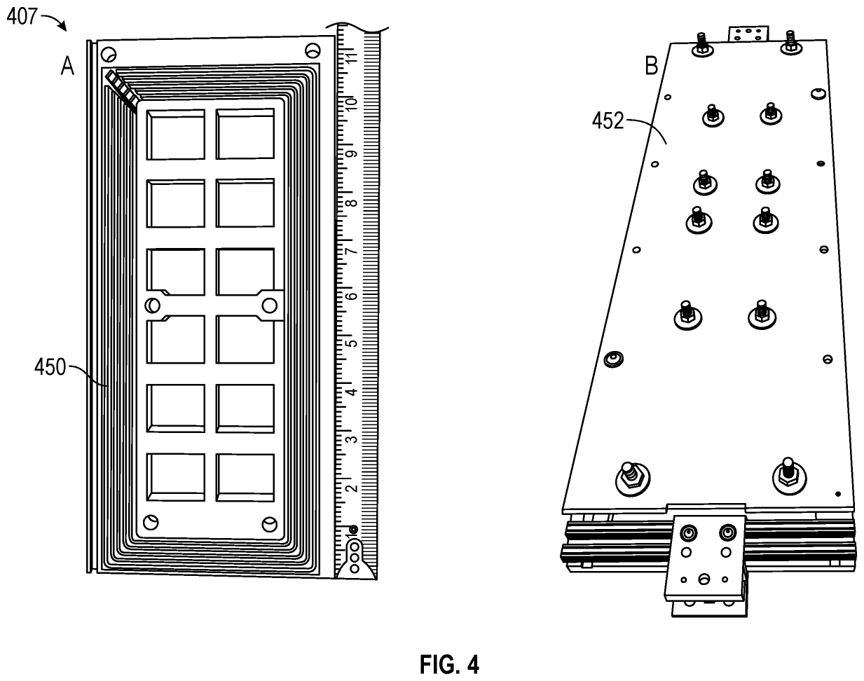

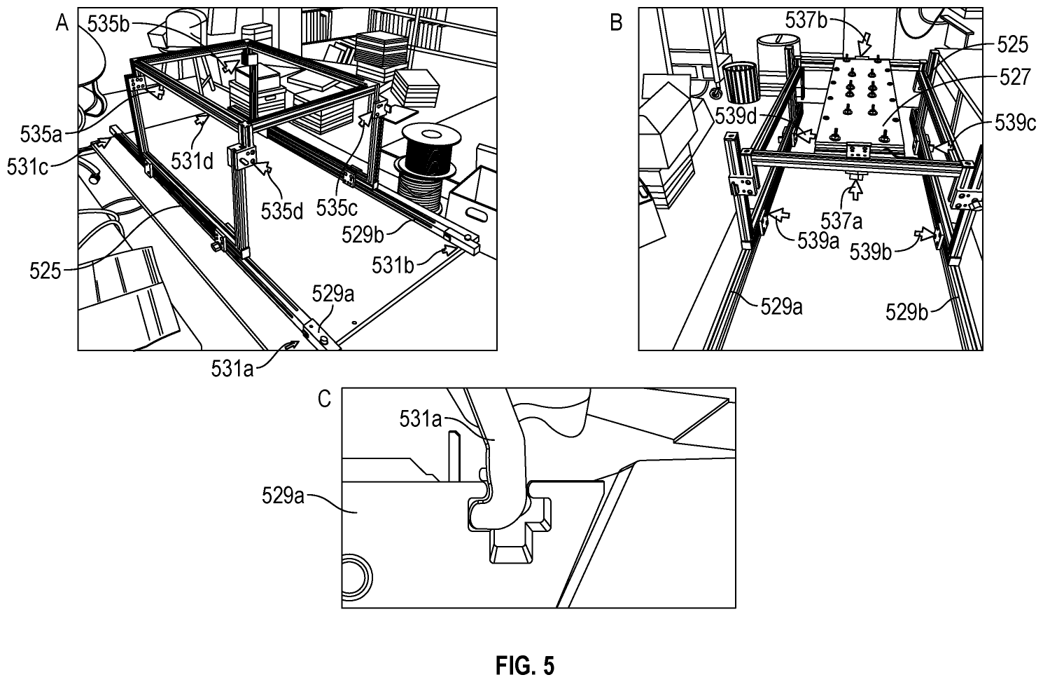

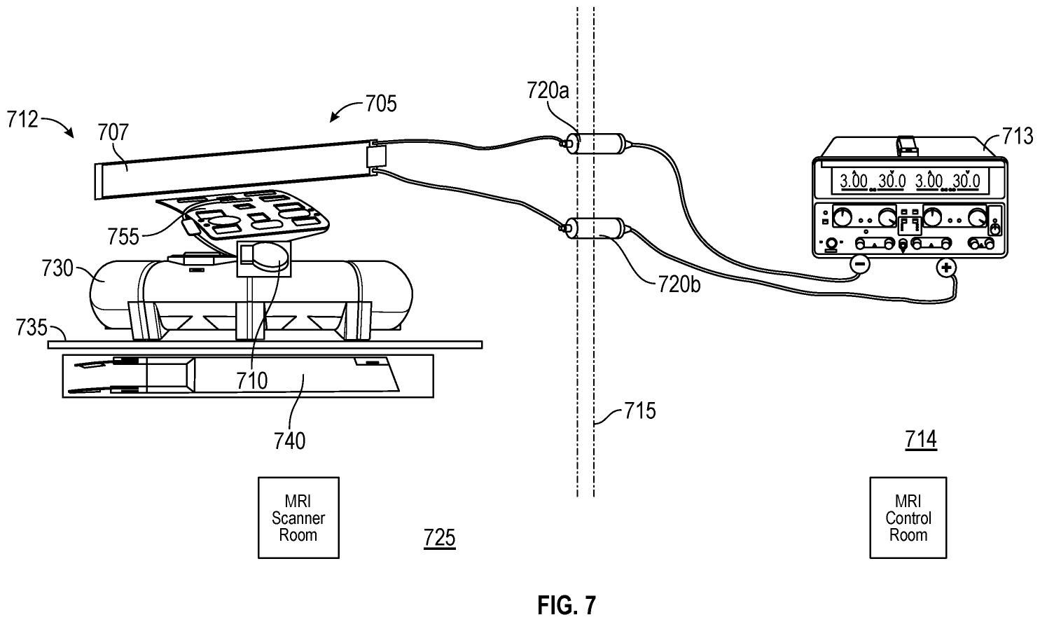

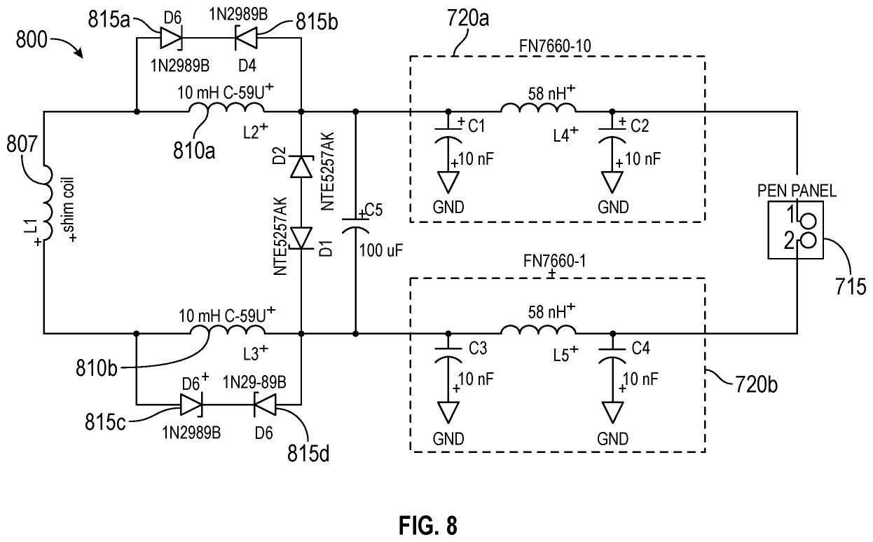

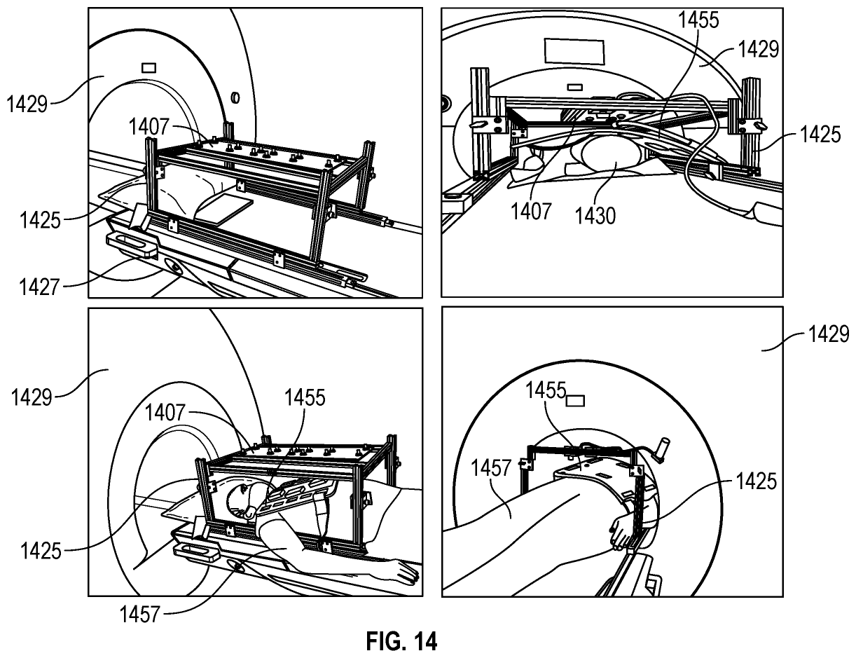

FIG. 4 shows an example of a balanced-force MRI shim coil assembly 407 used in some embodiments. The shim coil assembly 407 may be used, as non-limiting examples, as one or more of the shim coil assembly 107, the shim coil assembly 527 (FIG. 5), the shim coil assembly 707 (FIG. 7), the shim coil assembly 807 (FIG. 8), and the shim coil assembly 1407 (FIG. 14).

Panel A of FIG. 4 illustrates one segment 450 of the shim coil assembly 407, which is constructed of multiple windings which are placed and epoxied into a former. The other segment (not shown) of the shim coil assembly 407 has the same shape, is electrically connected in series with the first segment 450, and is laid folded above the first segment 450. Panel B of FIG. 4 illustrates the folded complete shim coil assembly 407, which is constructed of two such formers oriented in opposing directions, folded above each other, and electrically connected in series. The shim coil assembly 407 may then be placed inside a housing 452, and may be mounted on a frame assembly (see FIG. 5).

In some embodiments, the shim coil assembly 407 includes additional current segments, to reduce coupling of the shim coil assembly 407 to the gradient coil of the MR system without distorting a target field of view. Additional coil elements permit higher-order shimming, and/or larger field of view for larger ROIs. Imaging reconstruction algorithms are also used in some embodiments to correct for residual field distortions beyond the optimal dipole field correction.

In some embodiments, the shim coil assembly 407 may include MRI-visible markers that are used to register the location of the shim coil assembly 407 to the reference frame of the acquired MRI images. In some embodiments the coil former may be made of a material which is MRI-visible. In other embodiments, lasers or other optical methods may be used to perform spatial registration of the shim coil assembly 407 to the imaging reference frame.

Additional RF shielding may also be used for the shim coil assembly 407 in some embodiments. Use of such shielding may provide reduced loss of SNR, interference with MRI gradients during imaging, and may enable use of any imaging sequence, including sequences such as SSFP, which deliver exact gradient and RF patterns in order to display the correct inter-tissue contrast. Without such RF shielding, imaging may be largely limited to GRE sequences.

In some embodiments, the shim coil assembly 407 may be anchored strongly to the MRI stretcher so it cannot move freely or due to magnetic forces. However, it is desirable to move the shim coil assembly in 3 directions within the bore, after releasing its locks, to be centered properly. To accomplish this, a frame assembly is utilized in some embodiments, to permit moving the shim coil assembly in the left-right (X), up-down (Y) and superior-inferior (Z) directions.

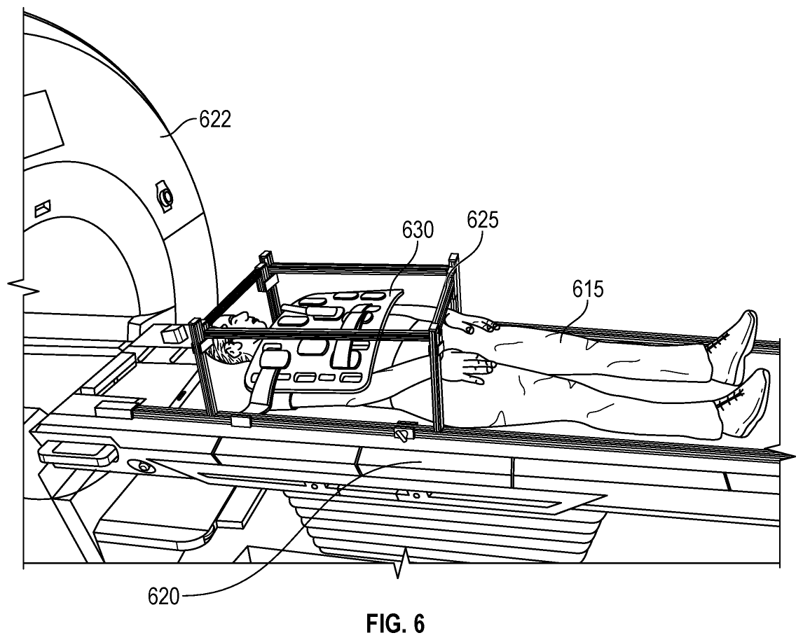

FIG. 5 shows multiple views of a frame assembly 525 of some embodiments. The frame assembly 525 may be used, as non-limiting examples, as the frame assembly 125 and the frame assembly 625 (FIG. 6).

The frame assembly 525 in this example is constructed of aluminum. In other embodiments, the frame assembly 525 may be made of a different non-ferrous material, metal, or metal alloy. In some embodiments, the frame assembly 525 may be made of a non-ferrous and non-conductive material, such as a plastic or composite.

Panel A of FIG. 5 shows the frame assembly 525 without a mounted shim coil, and panel B shows the frame assembly 525 with a mounted shim coil assembly 527. The frame assembly has two long railings 529a, 529b that can be placed on the sides of the MRI scanner bed (not shown) and locked to the bed using four dedicated plastic attachments (indicated by arrows 531a, 531b, 531c, 531d). Panel C of FIG. 5 shows a close-up of one of the plastic attachments that lock the railings 529a, 529b of the frame assembly 525 to a table. In this example, Siemens Healthineers (Erlangen, Germany) clips are used as the attachments.

The shim coil holder portion of the frame assembly 525 can be moved (e.g. slid) vertically in the Y direction (up and down, relative to the patient table). In this example, the vertical motion is enabled using four locks indicated by arrows 535a, 535b, 535c, and 535d. Two locks (indicated by arrows 537a, 537b) also allow moving the shim coil assembly 527 in the X direction (left and right, relative to the patient table) within the frame assembly 525, while keeping the frame assembly 525 stationary. In addition, four locks (indicated by arrows 539a, 539b, 539c, 539d) allow sliding the frame assembly 525 in and out of the magnet bore, along the railings 529a, 529b in the Z direction (superior-inferior, relative to the patient table).

Some embodiments also may incorporate ferromagnetic shim elements (e.g., thin steel strips) to improve cancellation of the ICD distortion as well as to reduce the amount of current needed for the shim coil assembly 527. Furthermore, in some embodiments, instead of mounting the shim coil assembly 527 to the frame assembly 525 within the bore, the shim coil assembly 527 may be cantilevered to provide more flexibility in the positioning of the device and maximize patient clearance size.

FIG. 6 illustrates a volunteer subject 615 on a patient table 620 of an MRI system 622, positioned inside a frame assembly 625. For purposes of illustration, no shim coil assembly is attached to the frame assembly 625 in this view. The frame assembly 625 is large enough in order to admit the human subject 615 and surface coils 630, and still fit into the bore of the MRI system 622. A shim coil assembly mounted to the frame assembly 625 can then be brought to the proper location, as determined by inhomogeneity correction software.

FIG. 7 conceptually illustrates a shimming system 705 for performing shim coil validation tests in some embodiments. The shimming system 705 may be used to test the utility of a shim coil assembly 707 in canceling the field of an ICD 710 during operation in an MRI system 712.

A DC power supply 713 in an MRI control room 714 outputs currents that go to a penetration panel 715, where radio frequency interference (RFI) filters 720a, 720b conduct the currents onwards into an RF-shielded MRI room 725, where the MRI system 712 is located. A cylindrical water phantom 730 is placed on an MRI stretcher 735, which has an MRI spine array receiver coil 740 underneath. The ICD 710 is placed on the upper outer surface of the cylindrical water phantom 730. An MRI body array receiver coil 755 is placed above the phantom 730, and the shim coil assembly 707 is positioned above the phantom 730, with the center of the shim coil assembly 707 lying immediately above the ICD 710.

The DC power supply 713, located outside the MRI room 725, is configured to drive a controlled amplitude of current (e.g., measured in Amperes) into the balanced-force shim coil assembly 707. The RFI filters 720a, 720b are placed on the MRI system's penetration panel 715 to prevent Radio Frequency (RF) noise from getting into the MRI room 725 on the electrical lines that carry current into the shim coil assembly 707. Inside the MRI room 725, the currents are carried on thick coaxial cables to the shim coil assembly 707 itself.

In some embodiments, the shim coil assembly 707 is configured so as to avoid introducing radio-frequency noise at the MRI frequency into the MRI system 712. For example, to avoid introducing such noise, the current generator (e.g., the DC power supply 713) and cabling may be filtered for radio-frequency interference.

FIG. 8 illustrates a schematic of a filter circuit 800 used in some embodiments for a shim coil assembly 807. The filter circuit 800 in this example is a low pass filter circuit which decouples the shim coil assembly 807 from the gradient coils (not shown) of the MR system 712 (FIG. 7). As discussed above, the penetration panel 715 is an interface panel located on a wall of the RF-shielded MRI room 725 (FIG. 7) that surrounds the MRI system 712, and provides a place to interface other equipment that may be used with the MRI system 712. Electrical interference from the equipment may be filtered at this point. The other side of the penetration panel 715 is the DC power supply (not shown in FIG. 8) for the shim coil assembly 807. The dashed boxes represent RFI filters 720a, 720b that are configured to attenuate signals at the scanner's operating frequency (e.g., 64 MHz for a 1.5T scanner). The decoupling circuit consists of 2 large inductors 810a, 810b (e.g., 10 milliHenry, or mH) which are configured to present a high impedance to the signals induced by the gradient coils of the MRI system 712 when they are switched on or off. As the inductors 810a, 810b may be large and (as in the embodiments shown in FIGS. 7 and 8) ferromagnetic, they may be carefully placed (and preferably fastened to the wall, so they cannot be accidently moved into the static magnetic field) near the penetration panel 715. As the shim coil assembly 807 operates with a constant current, the inductors 810a, 810b or the RFI filters 720a, 720b do not interfere. In addition, in some embodiments, power Zener diodes (e.g., diodes 815a, 815b, 815c, 815d) may also be placed across the inductors 810a, 810b to protect against over-voltages.

The decoupling is important as any induced currents in the shim coil assembly 807 from the gradient coils will introduce artifacts into the image. The value of the inductors used is dependent upon the gradient switching time and the desired decoupling as well as practical considerations such as size and MRI safety.

The shimming system 705 described above was used to experimentally test the concept. As discussed above, a cylindrical water phantom 730 was used with an ICD 710 placed on top of it, to emulate the clinical scenario depicted in FIG. 6. The cylinder phantom 730 was placed on the MRI stretcher 735, above the scanner's spine array receiver coil 740, with a body array receiver coil 755 also added above the phantom 730, which mirrors the case of a cardiac MRI subject. The shim coil assembly 707 was then moved so it was above the cylinder phantom 730, and the shim coil assembly 707 centered above the ICD 710.

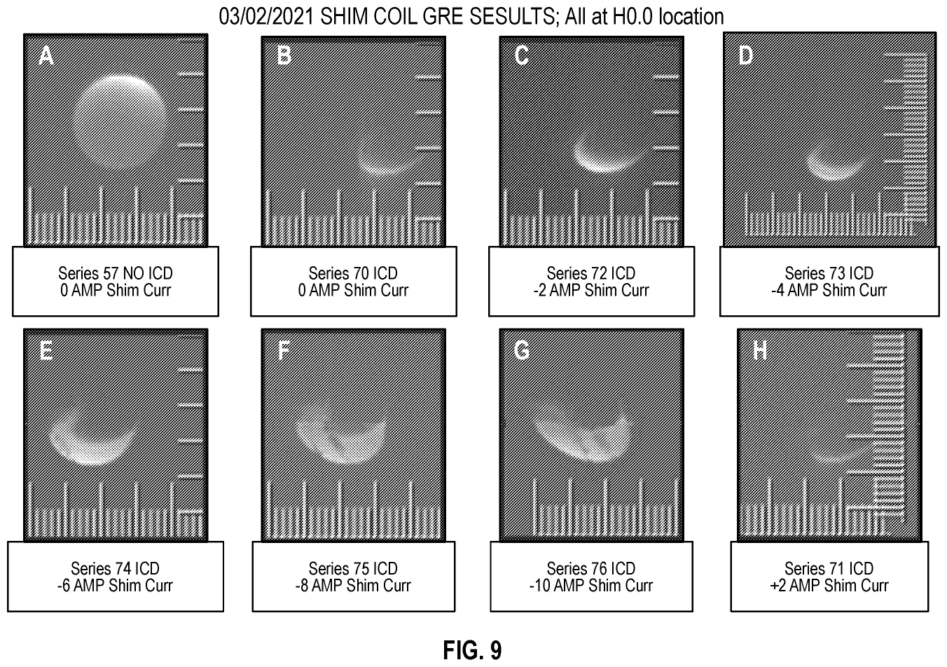

FIG. 9 illustrates the results of experimental testing using the shimming system 705. Panel A of FIG. 9 shows transverse GRE images of the cylindrical phantom 730 taken without the ICD 710. Panel B of FIG. 9 shows transverse GRE images of the phantom 730 with the ICD 710 mounted on its top, which strongly distorts the field and leads to only a small sliver of image still being visible, since the rest of the NMR spins are at larger field shifts than visible with the bandwidth of this sequence. Panels C to H of FIG. 9 show images with the ICD 710 at several settings of the shim coil current, and with the former of the shim coil assembly 707 placed ˜15 cm above the ICD 710. In FIG. 9, panel B illustrates no shim current, panel C illustrates a shim current of −2 Amperes, panel D illustrates a shim current of −4 Amperes, panel E illustrates a shim current of −6 Amperes, panel F illustrates a shim current of −8 Amperes, panel G illustrates a shim current of −10 Amperes, and panel H illustrates a shim current of +2 Amperes.

From the results of panels A to H, it is possible to see that presence of the ICD severely distorts the shape of the cylinder (compresses some portions and stretches others) and also erases (“blanks out”) the majority of its cross-section (e.g., panel B). However, the application of increasingly large negative polarity (−) current (panels C to G) recovers increasingly larger portions of the phantom (e.g., increases the size of the visible cylinder) and reduces its geometric distortion, whereas application of a positive polarity (+) current (FIG. 9H) increases the shape distortion beyond that seen in Panel B of FIG. 9 and erases a larger portion of the image.

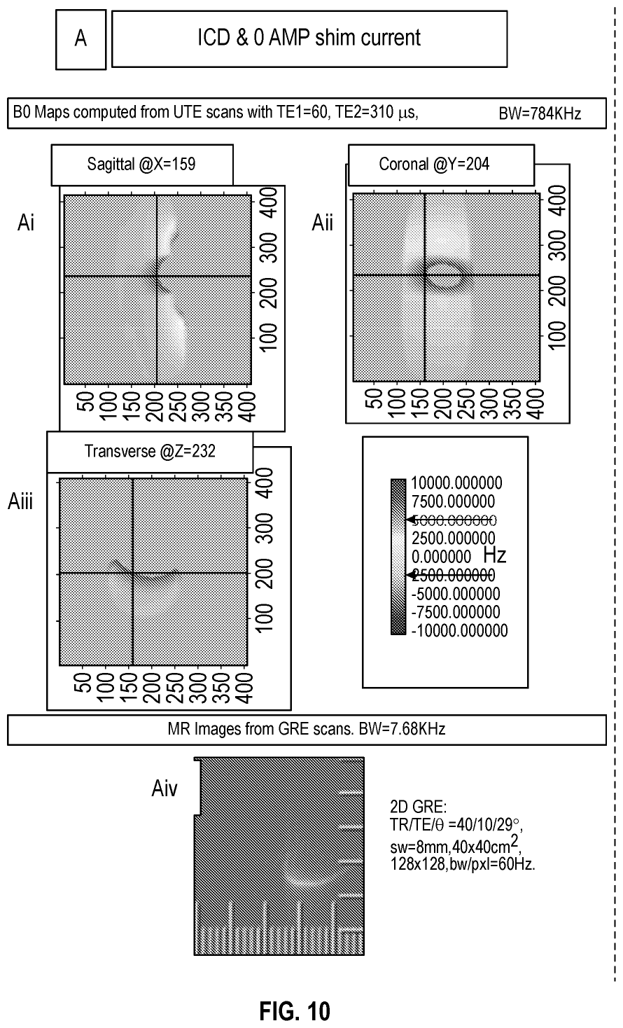

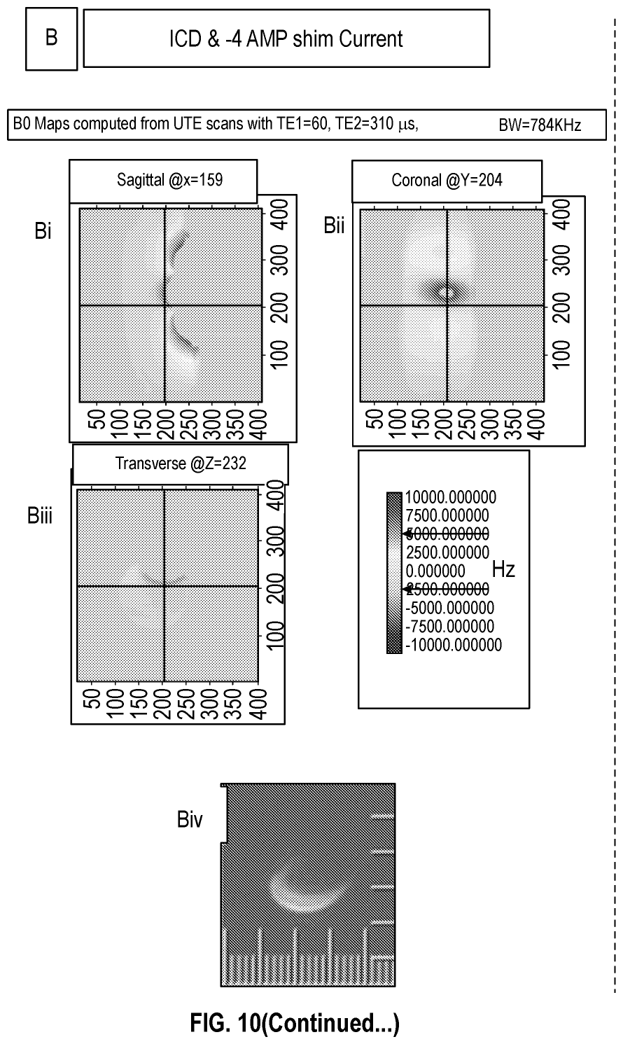

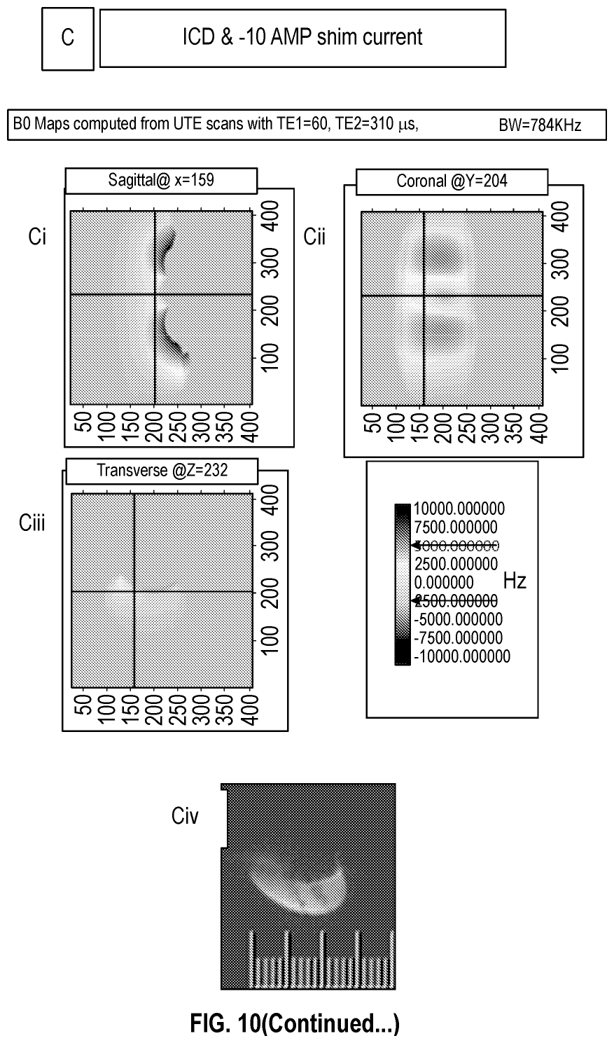

FIG. 10 illustrates magnetic field maps for the experiments in FIG. 9. These maps of the static field (BO) were obtained with the ICD in place at several current settings of the shim coil assembly 707 (Panel A=0 Ampere, panel B=−4 Ampere, and panel C=−10Ampere). The BO maps were obtained using ultra-short echo time (UTE) images that have a very broad bandwidth (e.g., 784 KHz). Sub-panels (i), (ii), and (iii) for each current setting show BO maps obtained in the sagittal, coronal, and axial planes, while sub-panel (iv) shows the respectively obtained GRE image, which has a much narrower bandwidth (7.68 KHz). The arrows on the legend of the color maps for (i)-(iii) display the range of the GRE sequence's sensitivity. The GRE MRI images A (iv)-C (iv) include only frequencies that are within the sensitive range. As the shim current increases from 0 AMP (panel A) to −10 AMP (panel C), more of the GRE image is observed, since much of the very strong field inhomogeneities have been corrected (compare, for example, the B0 map Cii with the B0 map Aii).

Since in this experiment, the mapping of the static magnetic field BO was performed at all of the current steps using a wideband (785 KHz, ˜1200 PPM) UTE sequence, it is possible to understand the effects seen in panels A to H of FIG. 9. In panel A, the B0 maps show strong inhomogeneities that lie outside the acceptance bandwidth of the GRE sequence (see arrows) and consequently result in the inability to see portions of the GRE image, while the geometric distortions seen in the images arise due to the large gradients in the BO field at the edges of the acceptance bandwidth which may cause an uneven distribution of spins within each image voxel, leading to compression of the shape (a process referred to as “spin pile up”).

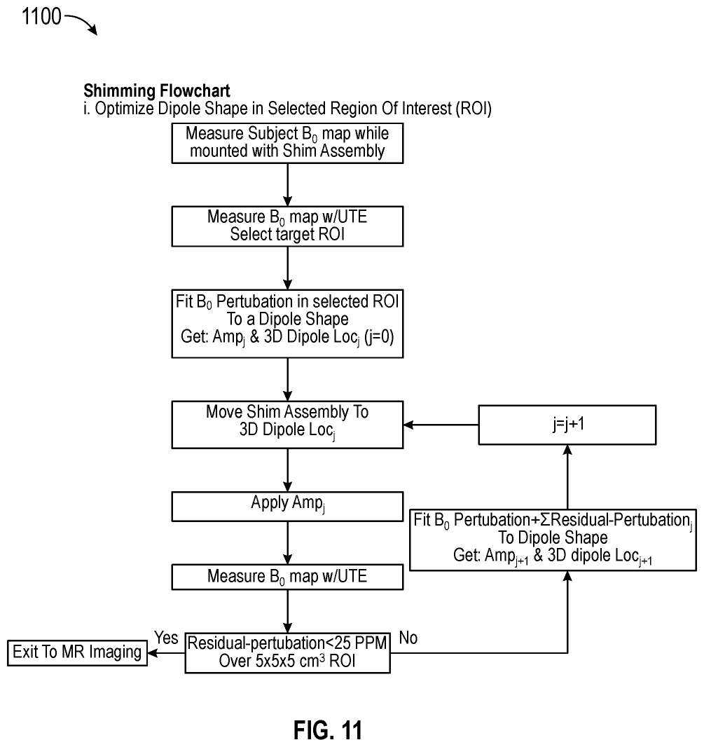

FIGS. 11, 12, and 13 shows procedure flowcharts that detail processes of different embodiments for performing effective shimming of field inhomogeneities in the heart using a shim coil assembly.

FIG. 11 illustrates a flowchart 1100 for a process in which the shape of the dipole model is optimized, so that it will better fit the field inhomogeneity in the region of interest (ROI). In this approach, the iteration is on the shape of the dipole. Once the residual perturbation is below 25 ppm within the ROI, MRI imaging of the patient is begun with the fitted values for current and shim coil location. This process may be relevant for very large field inhomogeneities, such as those even outside the acceptance bandwidth of the UTE sequence.

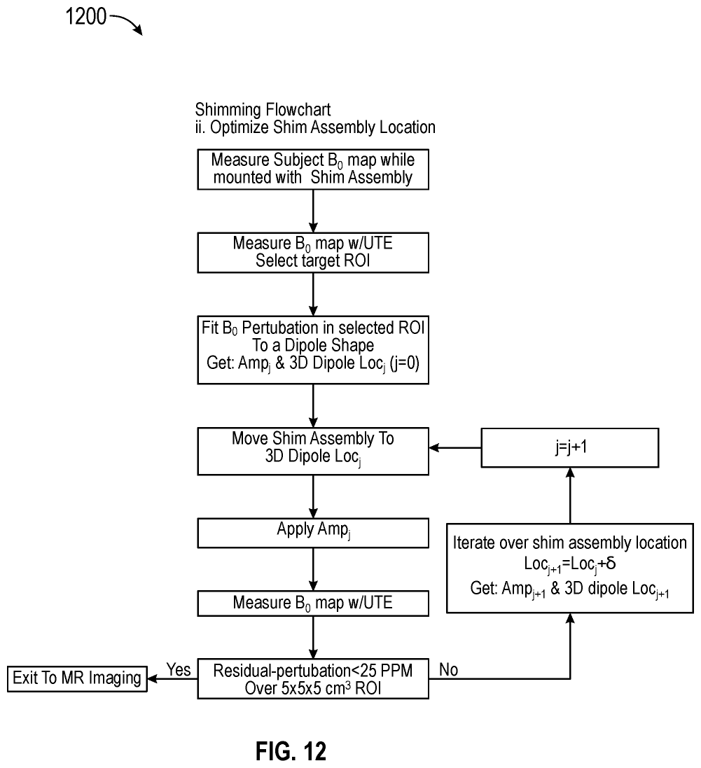

FIG. 12 illustrates a flowchart 1200 for a process in which the shim coil location is optimized in order to obtain the minimal bandwidth field possible. This process may be relevant in situations where imaging is desired with pulse sequences that are strongly affected by magnetic inhomogeneities, such as imaging with Steady State Free Precession (SSFP) or with Echo Planar Imaging (EPI) sequences.

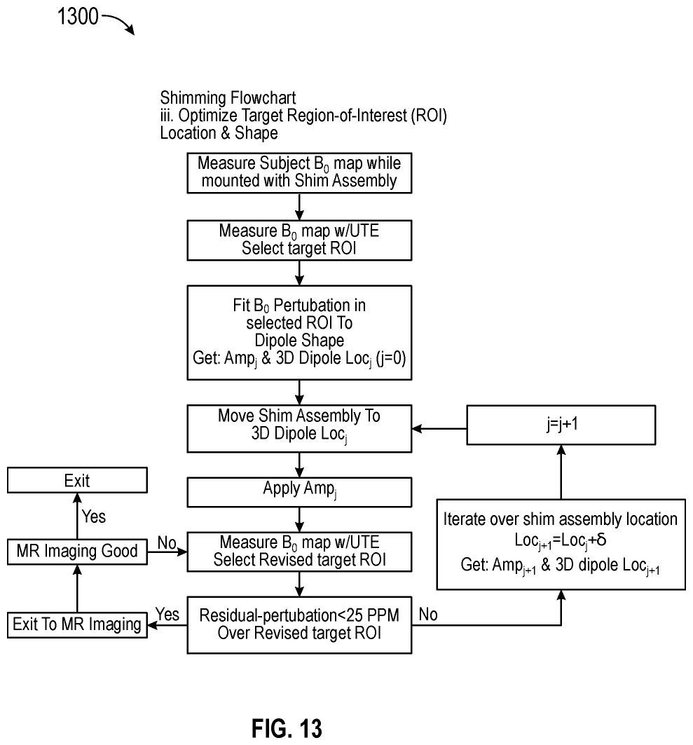

FIG. 13 illustrates a flowchart 1300 for a process in which the target ROI's location and shape are both optimized in order to obtain the best image of the pathology that is of interest. The flowchart 1300 is a combination of the flowchart 1100 in FIG. 11 and the flowchart 1200 in FIG. 12. The flowchart 1300 illustrated in FIG. 13 also illustrates that even after optimization, after performing MRI imaging there may still be concerns with image quality. In that case the process can begin anew with a new BO map.

FIG. 14 illustrates another embodiment of a shim coil assembly 1407 mounted to a plastic frame assembly 1425. FIG. 14 shows, from upper left to lower right, the plastic frame assembly 1425 mounted to the table 1427 of the MRI system 1429, the plastic frame assembly 1425 with a cylindrical phantom 1430 and mounted body array RF receiver coil 1455, the plastic frame assembly 1425 with a volunteer subject 1457 inside, with the mounted body array RF receiver coil 1455, and the plastic frame assembly 1425 with the subject 1457 and mounted body array receiver coil 1455, inside the bore of the MRI system 1429. The plastic frame assembly 1425 is non-ferrous and non-conductive, unlike most metals and metal alloys. This provides less interference to the MRI RF body array receiver coil 1455, with almost zero loading, and no SNR loss compared to the normal case of imaging without the plastic frame assembly 1425. The lack of plastic frame conductivity also provides no safety hazard of heating from excessive RF deposition, which can potentially injure a subject.

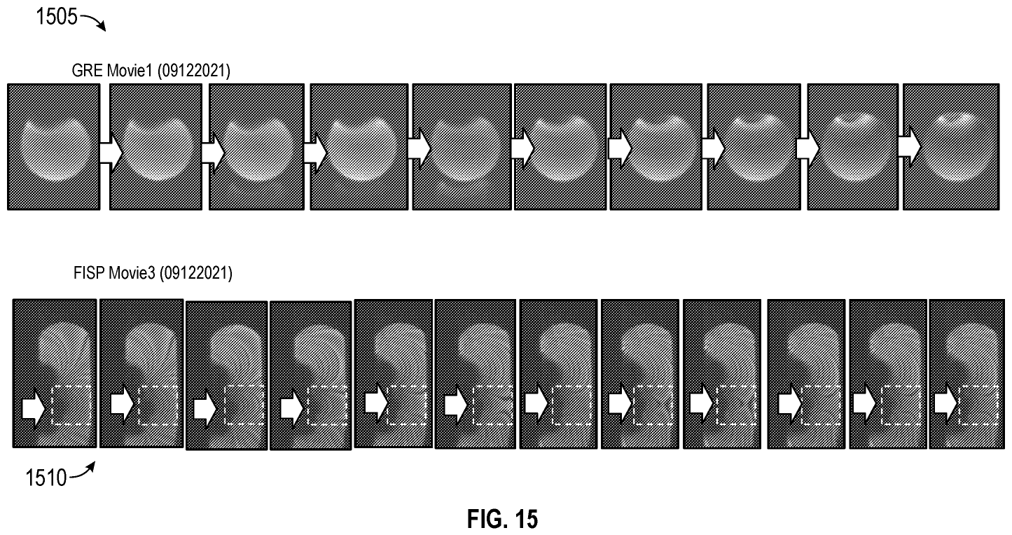

In some embodiments, the shimming system 705 includes a capability for real-time shimming, with a visual display of the shimming performance while changing settings (e.g. the current in the shim coil assembly 707, and the location of the shim coil assembly 707). FIG. 15 illustrates frames of video taken during real-time shimming for several different scenarios. In another experiment, ICD 710 was placed on the top surface of the cylindrical phantom 730, thereby reducing the homogeneity in that region. The shim coil assembly 707 was then placed above this inhomogeneous region and the current in the shim coil assembly 707 varied.

The top series 1505 in FIG. 15 is a series of images acquired at successive times in a 1.5 Tesla MRI using a GRE sequence, while changing the current in the shim coil assembly 707. The filling of the circle shows improved homogeneity, where the ICD void is the dark region at the top of the phantom 730.

The bottom series 1510 in FIG. 15 is a series acquired at successive times in a 1.5 Tesla MRI scanner using an SSFP sequence on the same phantom 730, while changing the current in the shim coil assembly 707. In this sequence the artifacts have a banded appearance, with dark gaps appearing approximately every 410 Hz. The void arising from the ICD 710 is the dark region on the left of each image, while the regions to the right of the void also suffer from reduced homogeneity. Examining successive frames and going progressively further to the right, as indicated by the arrows, it is possible to observe within the region of the dotted white rectangle an increasing distance between adjacent dark bands, which indicates a zone of improving magnetic field homogeneity.

The term “computer” is intended to have a broad meaning that may be used in computing devices such as, e.g., but not limited to, standalone or client or server devices. The computer may be, e.g., (but not limited to) a personal computer (PC) system running an operating system such as, e.g., (but not limited to) MICROSOFT® WINDOWS® NT/98/2000/XP/Vista/Windows 7/8/etc. available from MICROSOFT® Corporation of Redmond, Wash., U.S.A. or an Apple computer executing MACR OS from AppleR of Cupertino, Calif., U.S.A. However, the invention is not limited to these platforms. Instead, the invention may be implemented on any appropriate computer system running any appropriate operating system. In one illustrative embodiment, the present invention may be implemented on a computer system operating as discussed herein. The computer system may include, e.g., but is not limited to, a main memory, random access memory (RAM), and a secondary memory, etc. Main memory, random access memory (RAM), and a secondary memory, etc., may be a computer-readable medium that may be configured to store instructions configured to implement one or more embodiments and may comprise a random-access memory (RAM) that may include RAM devices, such as Dynamic RAM (DRAM) devices, flash memory devices, Static RAM (SRAM) devices, etc.

The secondary memory may include, for example, (but is not limited to) a hard disk drive and/or a removable storage drive, representing a floppy diskette drive, a magnetic tape drive, an optical disk drive, a compact disk drive CD-ROM, flash memory, etc. The removable storage drive may, e.g., but is not limited to, read from and/or write to a removable storage unit in a well-known manner. The removable storage unit, also called a program storage device or a computer program product, may represent, e.g., but is not limited to, a floppy disk, magnetic tape, optical disk, compact disk, etc. which may be read from and written to the removable storage drive. As will be appreciated, the removable storage unit may include a computer usable storage medium having stored therein computer software and/or data.

In alternative illustrative embodiments, the secondary memory may include other similar devices for allowing computer programs or other instructions to be loaded into the computer system. Such devices may include, for example, a removable storage unit and an interface. Examples of such may include a program cartridge and cartridge interface (such as, e.g., but not limited to, those found in video game devices), a removable memory chip (such as, e.g., but not limited to, an erasable programmable read only memory (EPROM), or programmable read only memory (PROM) and associated socket, and other removable storage units and interfaces, which may allow software and data to be transferred from the removable storage unit to the computer system.

The computer may also include an input device may include any mechanism or combination of mechanisms that may permit information to be input into the computer system from, e.g., a user. The input device may include logic configured to receive information for the computer system from, e.g. a user. Examples of the input device may include, e.g., but not limited to, a mouse, pen-based pointing device, or other pointing device such as a digitizer, a touch sensitive display device, and/or a keyboard or other data entry device (none of which are labeled). Other input devices may include, e.g., but not limited to, a biometric input device, a video source, an audio source, a microphone, a web cam, a video camera, and/or other camera. The input device may communicate with a processor either wired or wirelessly.

The computer may also include output devices which may include any mechanism or combination of mechanisms that may output information from a computer system. An output device may include logic configured to output information from the computer system. Embodiments of output device may include, e.g., but not limited to, display, and display interface, including displays, printers, speakers, cathode ray tubes (CRTs), plasma displays, light-emitting diode (LED) displays, liquid crystal displays (LCDs), printers, vacuum florescent displays (VFDs), surface-conduction electron-emitter displays (SEDs), field emission displays (FEDs), etc. The computer may include input/output (I/O) devices such as, e.g., (but not limited to) communications interface, cable and communications path, etc. These devices may include, e.g., but are not limited to, a network interface card, and/or modems. The output device may communicate with processor either wired or wirelessly. A communications interface may allow software and data to be transferred between the computer system and external devices.

The term “data processor” is intended to have a broad meaning that includes one or more processors, such as, e.g., but not limited to, local processors or processors that are connected to a communication infrastructure (e.g., but not limited to, a communications bus, cross-over bar, interconnect, or network, etc.). The term data processor may include any type of processor, microprocessor and/or processing logic that may interpret and execute instructions (e.g., for example, a field programmable gate array (FPGA)). The data processor may comprise a single device (e.g., for example, a single core) and/or a group of devices (e.g., multi-core). The data processor may include logic configured to execute computer-executable instructions configured to implement one or more embodiments. The instructions may reside in main memory or secondary memory. The data processor may also include multiple independent cores, such as a dual-core processor or a multi-core processor. The data processors may also include one or more graphics processing units (GPU) which may be in the form of a dedicated graphics card, an integrated graphics solution, and/or a hybrid graphics solution. The data processor may be onboard, external to other components, or both. Various illustrative software embodiments may be described in terms of this illustrative computer system. After reading this description, it will become apparent to a person skilled in the relevant art(s) how to implement the invention using other computer systems and/or architectures.

The term “data storage device” is intended to have a broad meaning that includes removable storage drive, a hard disk installed in hard disk drive, flash memories, removable discs, non-removable discs, etc. In addition, it should be noted that various forms of electromagnetic radiation, such as wireless communication, electrical communication carried over an electrically conductive wire (e.g., but not limited to twisted pair, CAT5, etc.) or an optical medium (e.g., but not limited to, optical fiber) and the like may be encoded to carry computer-executable instructions and/or computer data that embodiments of the invention on e.g., a communication network. These computer program products may provide software to the computer system. It should be noted that a computer-readable medium that comprises computer-executable instructions for execution in a processor may be configured to store various embodiments of the present invention.

The term “network” is intended to include any communication network, including a local area network (“LAN”), a wide area network (“WAN”), an Intranet, or a network of networks, such as the Internet.

The term “software” is meant to include firmware residing in read-only memory or applications stored in magnetic storage, which can be read into memory for processing by a processor. Also, in some embodiments, multiple software inventions can be implemented as sub-parts of a larger program while remaining distinct software inventions. In some embodiments, multiple software inventions can also be implemented as separate programs. Finally, any combination of separate programs that together implement a software invention described here is within the scope of the invention. In some embodiments, the software programs, when installed to operate on one or more electronic systems, define one or more specific machine implementations that execute and perform the operations of the software programs.

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described. Moreover, features described in connection with one embodiment may be used in conjunction with other embodiments, even if not explicitly stated above.

### REFERENCES

Friedman DJ, Parzynski CS, Varosy PD, Prutkin JM, Patton KK, Mithani A, Russo AM, Curtis JP, Al-Khatib SM. Trends and In-Hospital Outcomes Associated With Adoption of the Subcutaneous Implantable Cardioverter Defibrillator in the United States. JAMA Cardiol. 2016 Nov 1;1(8):900-911.

Do D. H. et al., MRI in Patients with Implanted Devices: Current Controversies, JACC 2016.

Simonetti OP, Gross D C. Cardiovascular Magnetic Resonance in Patients with Magnetic Resonance-Conditional Cardiac Implantable Electronic Devices: What Can We See? Circ Cardiovasc Imaging. 2016 May;9(5):e004970.

Muthalaly RG, Nerlekar N, Ge Y, Kwong RY, Nasis A. MRI in Patients with Cardiac Implantable Electronic Devices. Radiology. 2018 Nov;289(2):281-292.

Nordbeck P, Ertl G, Ritter O. Magnetic resonance imaging safety in pacemaker and implantable cardioverter defibrillator patients: how far have we come? Eur Heart J. 2015 Jun 21;36 (24):1505-11.

Stevens S M, Tung R, Rashid S, Gima J, Cote S, Pavez G, Khan S, Ennis DB, Finn JP, Boyle N, Shivkumar K, Hu P. Device artifact reduction for magnetic resonance imaging of patients with implantable cardioverter-defibrillators and ventricular tachycardia: late gadolinium enhancement correlation with electroanatomic mapping. Heart Rhythm. 2014 Feb;11(2):289-98.

Hargreaves BA, Wolters PW, Pauly KB, Pauly JM, Koch KM, Gold GE. Metal-induced artifacts in MRI. AJR Am J Roentgenol. 2011 Sep;197(3):547-55.

We claim:

1. A device for magnetic resonance artifact correction, comprising:
an array comprising a plurality of shim coils that are sequentially arranged to receive a current, wherein a first force on the array arising from an interaction of a magnetic field with the current in any one of the shim coils is balanced by a second force on the array arising from interactions of the magnetic field with the current in all other shim coils when the array is operated within an imaging volume of a magnetic resonance system;
a frame composed of non-ferromagnetic material positioned proximate to the imaging volume, the frame being configurable to provide selectable positioning of the array within the imaging volume; and
a signal processor configured to:
receive a measurement of a magnetic field inhomogeneity within a selected region of the imaging volume; and
using the measurement of the magnetic field inhomogeneity, determine a current for the shim coils and a set of coordinates for positioning the array within the imaging volume,
wherein applying the current to the array at the set of coordinates generates a correction field to reduce the magnetic field inhomogeneity within the selected region of the imaging volume.

2. The device of claim 1, the signal processor further configured to provide the set of coordinates to the frame to configure the frame to move the array to the set of coordinates.

3. The device of claim 1, wherein the measurement of the magnetic field inhomogeneity within the imaging volume is generated using a map of the magnetic field within the imaging volume.

4. The device of claim 3, the signal processor further configured to:
communicate with an RF system of the magnetic resonance system to receive a plurality of MR signals; and
using the plurality of MR signals, generate the map of the magnetic field.

5. The device of claim 4, wherein the MR signals are acquired using a dual echo ultrashort echo-time MR pulse sequence.

6. The device of claim 4, wherein the signal processor is further configured to:
communicate with the RF system to receive a second plurality of MR signals;
using the second plurality of MR signals, generate a second magnetic field map within the imaging volume;
perform a second measurement of the magnetic field inhomogeneity within the imaging volume by using the second magnetic field map; and
based on a determination that the magnetic field inhomogeneity is greater than a predefined threshold, determine a second set of coordinates for positioning the array within the imaging volume using the second measurement of the magnetic field inhomogeneity.

7. The device of claim 1, wherein the magnetic field inhomogeneity within the imaging volume arises from a ferromagnetic object proximate to the imaging volume.

8. The device of claim 7, wherein the ferromagnetic object is a component of an implantable cardioverter defibrillator implanted in a patient's chest, wherein the imaging volume comprises the patient's heart.

9. The device of claim 1, wherein each of the first and second forces comprise a torque on the array.

10. The device of claim 1, wherein the magnetic field inhomogeneity is between 0 mT and 0.15 mT, wherein the magnetic field inhomogeneity is reduced by the correction field to at most 0.1 mT.

11. The device of claim 1, wherein the device is electrically connected to a damping circuit, said damping circuit comprising a plurality of inductors and diodes arranged to reduce any additional currents induced in any one of the shim coils during operation of the magnetic resonance system while the array is positioned within the imaging volume, said additional currents arising from electromagnetic coupling between the shim coils and at least one of a magnetic field gradient system of the magnetic resonance system and an RF system of the magnetic resonance system.

12. A magnetic resonance system comprising:
a magnet system configured to provide a substantially homogenous magnetic field over an imaging volume in the absence of ferromagnetic materials proximate to the imaging volume;
a magnetic field gradient system positioned proximate to the imaging volume, the magnetic field gradient system being configured to generate spatial encoding in the substantially homogeneous magnetic field;
a radiofrequency (RF) system arranged proximate to the imaging volume and configured to acquire a plurality of MR signals from the imaging volume; and
a device for magnetic resonance artifact correction, comprising:
an array comprising a plurality of shim coils that are sequentially arranged to receive a current, wherein a first force on the array arising from an interaction of a magnetic field with the current in any one of the shim coils is balanced by a second force on the array arising from interactions of the magnetic field with the current in all other shim coils when the array is operated within the imaging volume;
a frame composed of non-ferromagnetic material positioned proximate to the imaging volume, the frame being configurable to provide selectable positioning of the array within the imaging volume; and
a signal processor configured to:
receive a measurement of a magnetic field inhomogeneity within a selected region of the imaging volume; and
using the measurement of the magnetic field inhomogeneity, determine a current for the shim coils and a set of coordinates for positioning the array within the imaging volume,
wherein applying the current to the array at the set of coordinates generates a correction field to reduce the magnetic field inhomogeneity within the selected region of the imaging volume.

13. The magnetic resonance system of claim 12, the signal processor further configured to provide the set of coordinates to the frame to configure the frame to move the array to the set of coordinates.

14. The magnetic resonance system of claim 12, wherein the measurement of the magnetic field inhomogeneity within the imaging volume is generated using a map of the magnetic field within the imaging volume.

15. The magnetic resonance system of claim 14, the signal processor further configured to:
communicate with the RF system to receive a plurality of MR signals; and
using the plurality of MR signals, generate the map of the magnetic field.

16. The magnetic resonance system of claim 15, wherein the MR signals are acquired using a dual echo ultrashort echo-time MR pulse sequence.

17. The magnetic resonance system of claim 15, wherein the signal processor is further configured to:
communicate with the RF system to receive a second plurality of MR signals;
using the second plurality of MR signals, generate a second magnetic field map within the imaging volume;
perform a second measurement of the magnetic field inhomogeneity within the imaging volume by using the second magnetic field map; and
based on a determination that the magnetic field inhomogeneity is greater than a predefined threshold, determine a second set of coordinates for positioning the array within the imaging volume using the second measurement of the magnetic field inhomogeneity.

18. The magnetic resonance system of claim 12, wherein the magnetic field inhomogeneity within the imaging volume arises from a ferromagnetic object proximate to the imaging volume.

19. The magnetic resonance system of claim 18, wherein the ferromagnetic object is a component of an implantable cardioverter defibrillator implanted in a patient's chest, wherein the imaging volume comprises the patient's heart.

20. The magnetic resonance system of claim 12, wherein each of the first and second forces comprise a torque on the array.

21. The magnetic resonance system of claim 12, wherein the magnetic field inhomogeneity is between 0 mT and 0.15 mT, wherein the magnetic field inhomogeneity is reduced by the correction field to at most 0.1 mT.

22. The magnetic resonance system of claim 12 further comprising a damping circuit that is electrically connected to the device, said damping circuit comprising a plurality of inductors and diodes arranged to reduce any additional currents induced in any one of the shim coils during operation of the magnetic resonance system while the array is positioned within the imaging volume, said additional currents arising from electromagnetic coupling between the shim coils and at least one of the magnetic field gradient system and the RF system.

23. The magnetic resonance system of claim 12, wherein the non-ferromagnetic material is also a non-conductive material.

24. The device of claim 1, wherein the non-ferromagnetic material is also a non-conductive material.
